(19) United States
(12) Patent Application Publication
(10) Pub. No.: US 2024/0007061 A1
(43) Pub. Date: Jan. 4, 2024

(54) PHOTODETECTOR CURRENT SENSING

(71) Applicant: Allegro MicroSystems, LLC, Manchester, NH (US)

(72) Inventors: John Quirk, Portland, OR (US); Archie Barter, Beaverton, OR (US)

(73) Assignee: Allegro MicroSystems, LLC, Manchester, NH (US)

(21) Appl. No.: 17/809,990

(22) Filed: Jun. 30, 2022

(51) Int. Cl. H03F 3/08; H03F 1/18

(52) U.S. Cl. CPC H03F 3/087; H03F 1/18; H03F 2200/372; H03F 2200/462

(57) ABSTRACT

Methods and apparatus for a photodetector system including a photodetector having first and second terminals, wherein the photodetector is configured to generate a current in response to light. A first amplifier has a first input coupled to the first terminal of the photodetector to generate a first output voltage signal corresponding to the current generated by the photodetector. A second amplifier has a first input coupled to the second terminal of the photodetector to generate a second output voltage signal corresponding to the current generated by the photodetector. The first and second amplifiers can have different linear ranges to improve the total linear range of the detector system.

### BACKGROUND

As is known in the art, detection systems can emit laser pulses and detect reflected return using photodetectors. For example, some known ranging systems can include laser radar (ladar), light-detection and ranging (lidar), and rangefinding systems, to measure the distance to objects in a scene. A laser ranging and imaging system emits a pulse toward a particular location and measures the return echoes to extract the range.

Conventional laser ranging systems generally work by emitting a laser pulse and recording the time it takes for the laser pulse to travel to a target, reflect, and return to a photoreceiver. The laser ranging instrument records the time of the outgoing pulse and records the time that a laser pulse returns. The difference between these two times is the time of flight to and from the target. Using the speed of light, the round-trip time of the pulses is used to calculate the distance to the target.

Conventional photodetector systems include an optical receiver having an amplifier coupled to a terminal of the photodetector. The amplifier may generate a voltage that corresponds to the current level generated by the photodetector.

### SUMMARY

Example embodiments of the disclosure provide methods and apparatus for a detection system including a photodetector, such as a photodiode, having respective amplifiers coupled to each terminal of the photodetector. By sensing current on the anode and cathode of a photodiode, additional linear range can be achieved as compared with conventional photodetector circuits. In addition, anode and cathode current sensing can improve receive sensitivity and improve overdrive recovery.

In one aspect, a photodetector system comprises: a photodetector having first and second terminals, wherein the photodetector is configured to generate a current in response to light; a first amplifier having a first input coupled to the first terminal of the photodetector to generate a first output voltage signal corresponding to the current generated by the photodetector; and a second amplifier having a first input coupled to the second terminal of the photodetector to generate a second output voltage signal corresponding to the current generated by the photodetector.

A system can further include one or more of the following features: the photodetector comprises a photodiode, and wherein the first terminal comprises a cathode and the second terminal comprise an anode, the first and second amplifiers have different linear ranges, the different linear ranges of the first and second amplifiers are combined, the first and second amplifiers have a same type of noise distribution, the type of noise distribution comprises a Gaussian distribution, the first and second amplifiers have the same noise distribution, a signal-to-noise ratio (SNR) of the detector system is better than a detector system having a single amplifier connected to a photodiode, the first amplifier is configured to supply current to the photodetector to reduce voltage droop and reduce overdrive recovery time, the first and second amplifiers comprise transimpedance amplifiers, the first amplifier includes a second input terminal configured to receive a first voltage threshold, and the second amplifier incudes a second input terminal configured to receive a second voltage threshold, a first feedback resistor coupled across the output of the first amplifier and the first input of the first amplifier, wherein the first input of the first amplifier comprises an inverting input, a second feedback resistor coupled across the output of the second amplifier and the first input of the second amplifier, wherein the first input of the second amplifier comprises an inverting input, and/or an RC network coupled between a bias voltage and the first input of the first amplifier.

In another aspect, a method comprises: employing a photodetector having first and second terminals, wherein the photodetector is configured to generate a current in response to light in a photodetector system; employing a first amplifier having a first input coupled to the first terminal of the photodetector to generate a first output voltage signal corresponding to the current generated by the photodetector; and employing a second amplifier having a first input coupled to the second terminal of the photodetector to generate a second output voltage signal corresponding to the current generated by the photodetector.

A method can further include one or more of the following features: the photodetector comprises a photodiode, and wherein the first terminal comprises a cathode and the second terminal comprise an anode, the first and second amplifiers have different linear ranges, the different linear ranges of the first and second amplifiers are combined, the first and second amplifiers have a same type of noise distribution, the type of noise distribution comprises a Gaussian distribution, the first and second amplifiers have the same noise distribution, a signal-to-noise ratio (SNR) of the detector system is better than a detector system having a single amplifier connected to a photodiode, the first amplifier is configured to supply current to the photodetector to reduce voltage droop and reduce overdrive recovery time, the first and second amplifiers comprise transimpedance amplifiers, the first amplifier includes a second input terminal configured to receive a first voltage threshold, and the second amplifier incudes a second input terminal configured to receive a second voltage threshold, a first feedback resistor coupled across the output of the first amplifier and the first input of the first amplifier, wherein the first input of the first amplifier comprises an inverting input, a second feedback resistor coupled across the output of the second amplifier and the first input of the second amplifier, wherein the first input of the second amplifier comprises an inverting input, and/or an RC network coupled between a bias voltage and the first input of the first amplifier.

### BRIEF DESCRIPTION OF THE DRAWINGS

The foregoing features of this invention, as well as the invention itself, may be more fully understood from the following description of the drawings in which:

FIG. 1 shows an example detector system having dual current sensing of a photodetector in accordance with example embodiments of the disclosure;

FIG. 2 shows an illustrative circuit that can form a portion of the system of FIG. 1;

FIG. 3 is an electrical model of a photodiode that can form a part of the circuit of FIG. 2;

FIG. 4 shows an illustrative circuit that can form a portion of the system of FIG. 1;

FIG. 5 is a graphical representation of example linear ranges that can be provided by the illustrative circuit of FIG. 4; and

FIG. 6 is a schematic representation of an example computer that can perform at least a portion of the processing described herein.

### DETAILED DESCRIPTION

Prior to describing example embodiments of the disclosure some information is provided. Laser ranging systems can include laser radar (ladar), light-detection and ranging (lidar), and rangefinding systems, which are generic terms for the same class of instrument that uses light to measure the distance to objects in a scene. This concept is similar to radar, except optical signals are used instead of radio waves. Similar to radar, a laser ranging and imaging system emits a pulse toward a particular location and measures the return echoes to extract the range.

Laser ranging systems generally work by emitting a laser pulse and recording the time it takes for the laser pulse to travel to a target, reflect, and return to a photoreceiver. The laser ranging instrument records the time of the outgoing pulse—either from a trigger or from calculations that use measurements of the scatter from the outgoing laser light—and then records the time that a laser pulse returns. The difference between these two times is the time of flight to and from the target. Using the speed of light, the round-trip time of the pulses is used to calculate the distance to the target.

Lidar systems may scan the beam across a target area to measure the distance to multiple points across the field of view, producing a full three-dimensional range profile of the surroundings. More advanced flash lidar cameras, for example, contain an array of detector elements, each able to record the time of flight to objects in their field of view.

When using light pulses to create images, the emitted pulse may intercept multiple objects, at different orientations, as the pulse traverses a 3D volume of space. The echoed laser-pulse waveform contains a temporal and amplitude imprint of the scene. By sampling the light echoes, a record of the interactions of the emitted pulse is extracted with the intercepted objects of the scene, allowing an accurate multi-dimensional image to be created. To simplify signal processing and reduce data storage, laser ranging and imaging can be dedicated to discrete-return systems, which record only the time of flight (TOF) of the first, or a few, individual target returns to obtain angle-angle-range images. In a discrete-return system, each recorded return corresponds, in principle, to an individual laser reflection (i.e., an echo from one particular reflecting surface, for example, a tree, pole or building). By recording just a few individual ranges, discrete-return systems simplify signal processing and reduce data storage, but they do so at the expense of lost target and scene reflectivity data. Because laser-pulse energy has significant associated costs and drives system size and weight, recording the TOF and pulse amplitude of more than one laser pulse return per transmitted pulse, to obtain angle-angle-range-intensity images, increases the amount of captured information per unit of pulse energy. All other things equal, capturing the full pulse return waveform offers significant advantages, such that the maximum data is extracted from the investment in average laser power. In full-waveform systems, each backscattered laser pulse received by the system is digitized at a high sampling rate (e.g., 500 MHz to 1.5 GHz). This process generates digitized waveforms (amplitude versus time) that may be processed to achieve higher-fidelity 3D images.

Of the various laser ranging instruments available, those with single-element photoreceivers generally obtain range data along a single range vector, at a fixed pointing angle. This type of instrument—which is, for example, commonly used by golfers and hunters—either obtains the range (R) to one or more targets along a single pointing angle or obtains the range and reflected pulse intensity (I) of one or more objects along a single pointing angle, resulting in the collection of pulse range-intensity data, (R,I)ᵢ, where i indicates the number of pulse returns captured for each outgoing laser pulse.

More generally, laser ranging instruments can collect ranging data over a portion of the solid angle of a sphere, defined by two angular coordinates (e.g., azimuth and elevation), which can be calibrated to three-dimensional (3D) rectilinear cartesian coordinate grids; these systems are generally referred to as 3D lidar and ladar instruments. The terms “lidar” and “ladar” are often used synonymously and, for the purposes of this discussion, the terms “3D lidar,” “scanned lidar,” or “lidar” are used to refer to these systems without loss of generality. 3D lidar instruments obtain three-dimensional (e.g., angle, angle, range) data sets. Conceptually, this would be equivalent to using a rangefinder and scanning it across a scene, capturing the range of objects in the scene to create a multi-dimensional image. When only the range is captured from the return laser pulses, these instruments obtain a 3D data set (e.g., angle, angle, range)ₙ, where the index n is used to reflect that a series of range-resolved laser pulse returns can be collected, not just the first reflection.

Some 3D lidar instruments are also capable of collecting the intensity of the reflected pulse returns generated by the objects located at the resolved (angle, angle, range) objects in the scene. When both the range and intensity are recorded, a multi-dimensional data set [e.g., angle, angle, (range-intensity)ₙ] is obtained. This is analogous to a video camera in which, for each instantaneous field of view (FOV), each effective camera pixel captures both the color and intensity of the scene observed through the lens. However, 3D lidar systems, instead capture the range to the object and the reflected pulse intensity.

Lidar systems can include different types of lasers, including those operating at different wavelengths, including those that are not visible (e.g., those operating at a wavelength of 840 nm or 905 nm), and in the near-infrared (e.g., those operating at a wavelength of 1064 nm or 1550 nm), and the thermal infrared including those operating at wavelengths known as the “eyesafe” spectral region (i.e., generally those operating at a wavelength beyond 1300-nm, which is blocked by the cornea), where ocular damage is less likely to occur. Lidar transmitters are generally invisible to the human eye. However, when the wavelength of the laser is close to the range of sensitivity of the human eye—roughly 350 nm to 730 nm—the light may pass through the cornea and be focused onto the retina, such that the energy of the laser pulse and/or the average power of the laser must be lowered to prevent ocular damage. Thus, a laser operating at, for example, 1550 nm, can—without causing ocular damage—generally have 200 times to 1 million times more laser pulse energy than a laser operating at 840 nm or 905 nm.

One challenge for a lidar system is detecting poorly reflective objects at long distance, which requires transmitting a laser pulse with enough energy that the return signal— reflected from the distant target—is of sufficient magnitude to be detected. To determine the minimum required laser transmission power, several factors must be considered. For instance, the magnitude of the pulse returns scattering from the diffuse objects in a scene is proportional to their range and the intensity of the return pulses generally scales with distance according to 1/R\hat{ }4 for small objects and 1/R\hat{ }2 for larger objects; yet, for highly-specularly reflecting objects (i.e., those reflective objects that are not diffusively-scattering objects), the collimated laser beams can be directly reflected back, largely unattenuated. This means that—if the laser pulse is transmitted, then reflected from a target 1 meter away—it is possible that the full energy (J) from the laser pulse will be reflected into the photoreceiver; but—if the laser pulse is transmitted, then reflected from a target 333 meters away—it is possible that the return will have a pulse with energy approximately 10\hat{ }12 weaker than the transmitted energy. To provide an indication of the magnitude of this scale, the 12 orders of magnitude (10\hat{ }12) is roughly the equivalent of: the number of inches from the earth to the sun, 10× the number of seconds that have elapsed since Cleopatra was born, or the ratio of the luminous output from a phosphorescent watch dial, one hour in the dark, to the luminous output of the solar disk at noon.

In many cases of lidar systems highly-sensitive photoreceivers are used to increase the system sensitivity to reduce the amount of laser pulse energy that is needed to reach poorly reflective targets at the longest distances required, and to maintain eyesafe operation. Some variants of these detectors include those that incorporate photodiodes, and/or offer gain, such as avalanche photodiodes (APDs) or single-photon avalanche detectors (SPADs). These variants can be configured as single-element detectors, segmented-detectors, linear detector arrays, or area detector arrays. Using highly sensitive detectors such as APDs or SPADs reduces the amount of laser pulse energy required for long-distance ranging to poorly reflective targets. The technological challenge of these photodetectors is that they must also be able to accommodate the incredibly large dynamic range of signal amplitudes.

As dictated by the properties of the optics, the focus of a laser return changes as a function of range; as a result, near objects are often out of focus. Furthermore, also as dictated by the properties of the optics, the location and size of the “blur”—i.e., the spatial extent of the optical signal—changes as a function of range, much like in a standard camera. These challenges are commonly addressed by using large detectors, segmented detectors, or multi-element detectors to capture all of the light or just a portion of the light over the full-distance range of objects. It is generally advisable to design the optics such that reflections from close objects are blurred, so that a portion of the optical energy does not reach the detector or is spread between multiple detectors. This design strategy reduces the dynamic range requirements of the detector and prevents the detector from damage.

Acquisition of the lidar imagery can include, for example, a 3D lidar system embedded in the front of car, where the 3D lidar system, includes a laser transmitter with any necessary optics, a single-element photoreceiver with any necessary dedicated or shared optics, and an optical scanner used to scan (“paint”) the laser over the scene. Generating a full-frame 3D lidar range image—where the field of view is 20 degrees by 60 degrees and the angular resolution is 0.1 degrees (10 samples per degree)—requires emitting 120,000 pulses [(20*10*60*10)=120,000)]. When update rates of 30 frames per second are required, such as is required for automotive lidar, roughly 3.6 million pulses per second must be generated and their returns captured.

There are many ways to combine and configure the elements of the lidar system including considerations for the laser pulse energy, beam divergence, detector array size and array format (single element, linear, 2D array), and scanner to obtain a 3D image. If higher power lasers are deployed, pixelated detector arrays can be used, in which case the divergence of the laser would be mapped to a wider field of view relative to that of the detector array, and the laser pulse energy would need to be increased to match the proportionally larger field of view. For example—compared to the 3D lidar above—to obtain same-resolution 3D lidar images 30 times per second, a 120,000-element detector array (e.g., 200×600 elements) could be used with a laser that has pulse energy that is 120,000 times greater. The advantage of this “flash lidar” system is that it does not require an optical scanner; the disadvantages are that the larger laser results in a larger, heavier system that consumes more power, and that it is possible that the required higher pulse energy of the laser will be capable of causing ocular damage. The maximum average laser power and maximum pulse energy are limited by the requirement for the system to be eyesafe.

As noted above, while many lidar system operate by recording only the laser time of flight and using that data to obtain the distance to the first target return (closest) target, some lidar systems are capable of capturing both the range and intensity of one or multiple target returns created from each laser pulse. For example, for a lidar system that is capable of recording multiple laser pulse returns, the system can detect and record the range and intensity of multiple returns from a single transmitted pulse. In such a multi-pulse lidar system, the range and intensity of a return pulse from a closer-by object can be recorded, as well as the range and intensity of later reflection(s) of that pulse—one(s) that moved past the closer-by object and later reflected off of more-distant object(s). Similarly, if glint from the sun reflecting from dust in the air or another laser pulse is detected and mistakenly recorded, a multi-pulse lidar system allows for the return from the actual targets in the field of view to still be obtained.

The amplitude of the pulse return is primarily dependent on the specular and diffuse reflectivity of the target, the size of the target, and the orientation of the target. Laser returns from close, highly-reflective objects, are many orders of magnitude greater in intensity than the intensity of returns from distant targets. Many lidar systems require highly sensitive photodetectors, for example APDs, which along with their CMOS amplification circuits may be damaged by very intense laser pulse returns.

For example, if an automobile equipped with a front-end lidar system were to pull up behind another car at a stoplight, the reflection off of the license plate may be significant perhaps 10\hat{ }12 higher than the pulse returns from targets at the distance limits of the lidar system. When a bright laser pulse is incident on the photoreceiver, the large current flow through the photodetector can damage the detector, or the large currents from the photodetector can cause the voltage to exceed the rated limits of the CMOS electronic amplification circuits, causing damage. For this reason, it is generally advisable to design the optics such that the reflections from close objects are blurred, so that a portion of the optical energy does not reach the detector or is spread between multiple detectors.

However, capturing the intensity of pulses over a larger dynamic range associated with laser ranging may be challenging because the signals are too large to capture directly. One can infer the intensity by using a recording of a bit-modulated output obtained using serial-bit encoding obtained from one or more voltage threshold levels. This technique is often referred to as time-over-threshold (TOT) recording or, when multiple-thresholds are used, multiple time-over-threshold (MTOT) recording.

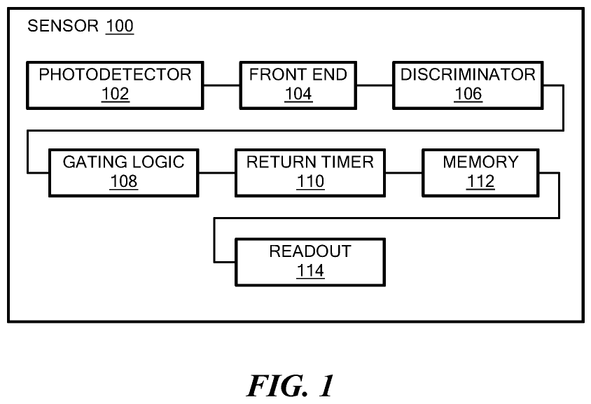

FIG. 1 shows an example LIDAR time-of-flight sensor 100 having photodetectors, such as photodiodes with dual current sensing, for a photodetector 102 array to detect photons reflected from a target illuminated with transmitted energy. A front-end circuit 104, which may include an amplifier for example, receives a current pulse generated by an optical pulse on the photodiode 102 and converts the current signal into an output, for example, an output voltage pulse. A discriminator circuit 106, such as a voltage discriminator, can determine if the current pulse, or its representation after signal conversion by the front-end circuit, is above one or more thresholds. Gating logic 108 receives an output from the discriminator 106 to match received signals with transmitted signals, for example. A return timer circuit 110, which can include a time-to-digital converter (TDC) for generating time-stamps, can determine the time from signal transmission to signal return so that a distance from the sensor to the target can be determined based on so-called time of flight. A memory 112 can store signal information, such as time of flight, time over threshold, and the like. A readout circuit 114-enables information to be read from the sensor.

A data processing and calibration circuit may be inserted between the memories 112 and the readout 114 which may perform any number of data correction or mapping functions. For example, the circuit may compare timing return information to timing reference information and convert timing return information into specific range information. Additionally, the circuit may correct for static or dynamic errors using calibration and correction algorithms. Other possible functions include noise reduction based on multi-return data or spatial correlation or objection detection. A possible mapping function may be to reshape the data into point-cloud data or to include additional probability data of correct measurement values based on additionally collected information from the sensor.

While example embodiments of the disclosure are shown and described in conjunction with LIDAR/LADAR systems, it is understood that embodiments of the disclosure are applicable to sensors in general in which at least dual current sensing for the sensor is desirable for noise improvement and/or other operating characteristics.

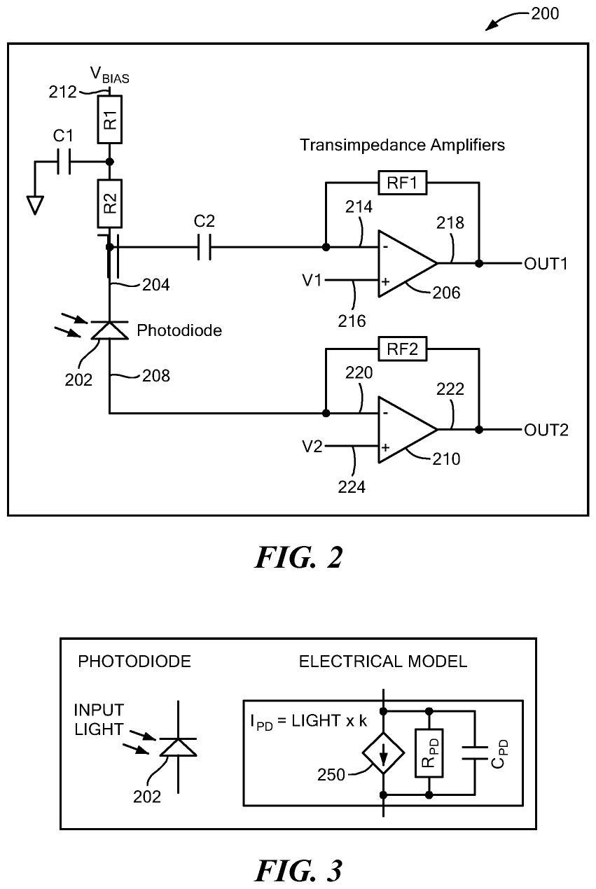

FIG. 2 shows a portion of an example optical receiver 200 having a photodetector 202, such as a photodiode, having a first terminal 204, shown as a cathode, coupled to a first amplifier 206 and a second terminal 208, shown as an anode, coupled to a second amplifier 210. The cathode 204 is coupled to a bias voltage source 212. In example embodiments, an RC network can include noise filtering of the photodiode power supply 202 with a first capacitor C1 coupled between first and second resistors R1, R2.

A first input 214 of the first amplifier 206 can be coupled to the first terminal 204 of the photodiode 202 via a second capacitor C2 with a first feedback resistor RF1 coupled to an output 218 of the first amplifier. A second input 216 of the first amplifier 206 can be coupled to a first voltage threshold V1. The first amplifier 206 generates a first output signal OUT1 on an output terminal 218 that is active when the signal from the cathode 204 exceeds the first voltage threshold V1.

A first input 220 of the second amplifier 210 can be coupled to the second terminal 208 of the photodiode 202 with a second feedback resistor RF2 coupled to an output 222 of the second amplifier. A second input 224 of the second amplifier 210 can be coupled to a second voltage threshold V2. The second amplifier 210 generates a second output signal OUT2 on the output terminal 222 that is active when the signal from the anode 208 on the second input 220 exceeds the second voltage threshold V2.

In embodiments, the first and second amplifiers 206, 210 receive currents of the same magnitude but having different directions. Current flows out of the first amplifier 206 (see FIG. 2) then through the bypass capacitor C2 through photodiode 202 and then into the second amplifier 210. In this configuration, the first amplifier 206 has a positive going signal and the second amplifier 210 has a negative going signal which can form a differential signal pair suitable for a following differential input amplifier, for example.

In example embodiments, the first and/or second amplifiers 206, 210 can be provided as transimpedance amplifiers which convert current to voltage. Transimpedance amplifiers are useful with sensors, such as photodiodes, that have a current response that is more linear than the voltage response. The transimpedance amplifier provides a low impedance to the photodiode and isolates the photodiode from the output voltage of the operational amplifier. The feedback resistor for the amplifier sets the gain of the transimpedance amplifier which is in an inverting configuration.

As shown in FIG. 3, the photodiode 202 can be modeled as a current source 250 connected to the inverting input of the transimpedance amplifier which provides a low-impedance load for the photodiode, and thus, a low photodiode voltage. The photodiode model includes a resistive component R_{PD} and a capacitive component C_{PD}. The current generated by the photodiode corresponds to the amount of light, which may be measured as photons per unit area, multiplied by a constant k.

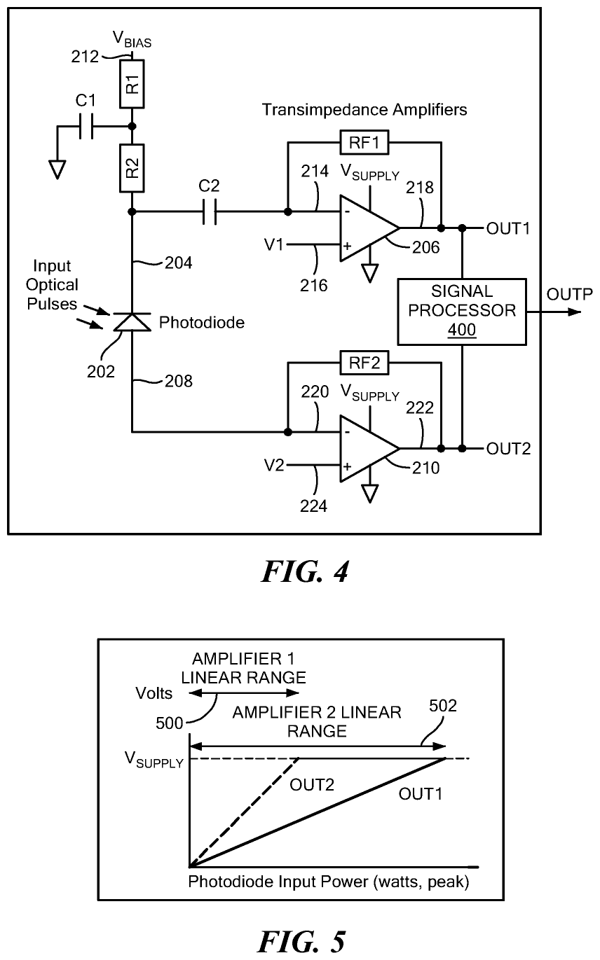

FIG. 4 shows an example circuit implementation having some commonality with circuit of FIG. 2 with the addition of a signal processor 400 to combine the outputs of the first and second amplifiers 206, 210. The use of first and second amplifiers can improve the linear range of a receiver for applications in which the output is linearly related to the input. Linear range may be limited by supply voltage, amplifier characteristics and/or gain-setting resistors RF. If RF1 for the first amplifier 206 does not equal RF2 for the second amplifier 210, the combination of OUT1 and OUT2 has increased linear range as compared to conventional single amplifier configurations.

As shown in FIG. 5, RF1 has a different resistance value than RF2 so that the first amplifier 206 has a first linear range 500 for a voltage (up to a maximum of supply voltage) across photodiode input power and the second amplifier 210 has a second linear range 502. As can be seen, the linear ranges 500, 502 for the first and second amplifiers 206, 210 are plotted as voltage, which may be limited by the supply voltage V_{SUPPLY}, versus photodiode input power, e.g., Watts, peak.

Referring again to FIG. 4, it is understood that the signal processor 400 can combine the first and second outputs OUT1, OUT2 in wide variety of ways to meet the needs of a particular application for achieving a desired linear range. The signal processor 400 can generate a processed output signal OUTP generated from some combination of first and second outputs OUT1, OUT2. In one embodiment, photodiode power level determines which of the first and second outputs OUT1, OUT2 is used. In some embodiments, any overlap of the first and second outputs OUT1, OUT2 is combined. In embodiments, the signal processor 400 considers both the amplitude and width of pulses detected at OUT1 & OUT2.

It is understood that the signal processor 400 can be implemented in analog circuitry, digital circuitry, combinations of analog and digital circuitry, in any suitable component, such as amplifiers, comparators, amplifiers, logic gates, and/or programmable circuitry.

Embodiments of the disclosure can improve noise performance, such as by improving receiver signal-to-noise ratio (SNR), as compared to conventional single amplifier circuits. As will be readily appreciated by one of ordinary skill in the art, low noise is very desirable for many applications.

It is common that noise of amplifiers is greater than noise of photodiode so that SNR is often determined by receiver amplifiers. In embodiments of the disclosure, first and second amplifiers receive the same signal, e.g., current, from the photodiode. Assume for example that the signal-to-noise ratio (SNR) of a single amplifier is P_{SIGNAL}/iₙₒᵢₛₑ, where iₙₒᵢₛₑ is a normal, e.g., gaussian, type noise measured under the conditions of the application. The noise of separate amplifiers is uncorrelated and adds in quadrature in accordance with the Central Limit Theorem. Therefore, the SNR of dual amplifier configuration is 2*P_{SIGNAL}/(1.4)*iₙₒᵢₛₑ, which is an improvement of 1.4× compared to a single amplifier. In example embodiments, the combined noise of uncorrelated amplifiers can be computed as sqrt(iₙₒᵢₛₑ²+iₙₒᵢₛₑ²)=1.4*iₙₒᵢₛₑ.

In view of the above, it will be understood that achieving noise reduction is optimized for amplifiers having the same noise distribution during operation. As used herein the term “same noise distribution” refers to selecting the same noise distribution to within relevant manufacturing tolerances. It is understood that components of the exact same type inherently have different operating characteristics. For example, first and second amplifiers with the same part number having the same specified noise distribution will have a slightly different noise distribution in operation since no two components are exactly alike.

In example embodiments, dual amplifier configurations may also improve overdrive recovery. Referring again to FIG. 4, the first amplifier 206 may supply additional current to the photodiode 202, which can reduce voltage droop and improve overdrive recovery time. In some applications, it is desired that the receiver always operates with best SNR, even when a very large input signal is applied. The time that a receiver operates with reduced SNR in response to a large input is referred to as overdrive recovery time.

The bias voltage V BIAS may causes the sensor 200 to operate in a useful mode. The filter effect of R1 and C1 isolates noise from the bias voltage generator circuit. A large optical input signal draws current from C1, thereby changing the voltage bias and gain characteristic of the photodiode 202. During this time, receiver 200 sensitivity may be reduced. In a conventional implementation, the photodiode bias recovers at a time constant set by C1 and R1.

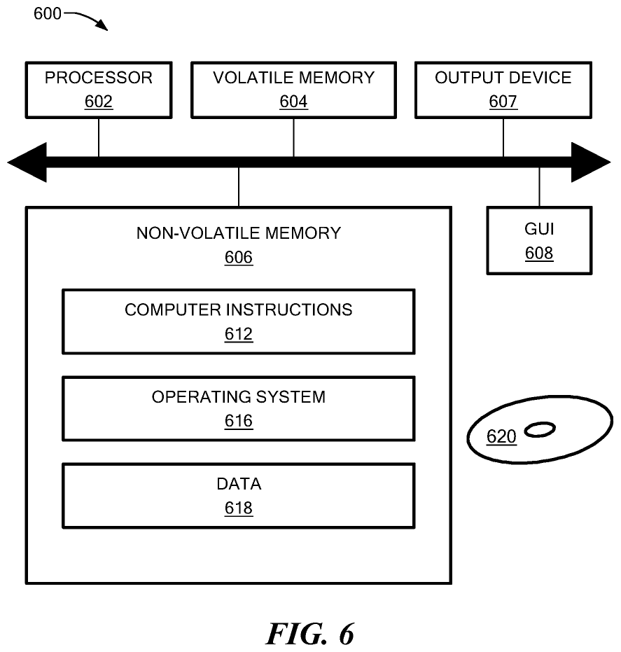

FIG. 6 shows an exemplary computer 600 that can perform at least part of the processing described herein. The computer 600 includes a processor 602, a volatile memory 604, a non-volatile memory 606 (e.g., hard disk), an output device 607 and a graphical user interface (GUI) 608 (e.g., a mouse, a keyboard, a display, for example). The non-volatile memory 606 stores computer instructions 612, an operating system 616 and data 618. In one example, the computer instructions 612 are executed by the processor 602 out of volatile memory 604. In one embodiment, an article 620 comprises non-transitory computer-readable instructions.

Processing may be implemented in hardware, software, or a combination of the two. Processing may be implemented in computer programs executed on programmable computers/machines that each includes a processor, a storage medium or other article of manufacture that is readable by the processor (including volatile and non-volatile memory and/or storage elements), at least one input device, and one or more output devices. Program code may be applied to data entered using an input device to perform processing and to generate output information.

The system can perform processing, at least in part, via a computer program product, (e.g., in a machine-readable storage device), for execution by, or to control the operation of, data processing apparatus (e.g., a programmable processor, a computer, or multiple computers). Each such program may be implemented in a high level procedural or object-oriented programming language to communicate with a computer system. However, the programs may be implemented in assembly or machine language. The language may be a compiled or an interpreted language and it may be deployed in any form, including as a stand-alone program or as a module, component, subroutine, or other unit suitable for use in a computing environment. A computer program may be deployed to be executed on one computer or on multiple computers at one site or distributed across multiple sites and interconnected by a communication network. A computer program may be stored on a storage medium or device (e.g., CD-ROM, hard disk, or magnetic diskette) that is readable by a general or special purpose programmable computer for configuring and operating the computer when the storage medium or device is read by the computer. Processing may also be implemented as a machine-readable storage medium, configured with a computer program, where upon execution, instructions in the computer program cause the computer to operate.

Processing may be performed by one or more programmable processors executing one or more computer programs to perform the functions of the system. All or part of the system may be implemented as, special purpose logic circuitry (e.g., an FPGA (field programmable gate array) and/or an ASIC (application-specific integrated circuit)).

Having described exemplary embodiments of the invention, it will now become apparent to one of ordinary skill in the art that other embodiments incorporating their concepts may also be used. The embodiments contained herein should not be limited to disclosed embodiments but rather should be limited only by the spirit and scope of the appended claims. All publications and references cited herein are expressly incorporated herein by reference in their entirety.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

What is claimed is:

1. A photodetector system, comprising:
a photodetector having first and second terminals, wherein the photodetector is configured to generate a current in response to light;
a first amplifier having a first input coupled to the first terminal of the photodetector to generate a first output voltage signal corresponding to the current generated by the photodetector; and
a second amplifier having a first input coupled to the second terminal of the photodetector to generate a second output voltage signal corresponding to the current generated by the photodetector.

2. The system according to claim 1, wherein the photodetector comprises a photodiode, and wherein the first terminal comprises a cathode and the second terminal comprise an anode.

3. The system according to claim 1, wherein the first and second amplifiers have different linear ranges.

4. The system according to claim 3, wherein the different linear ranges of the first and second amplifiers are combined.

5. The system according to claim 1, wherein the first and second amplifiers have a same type of noise distribution.

6. The system according to claim 5, wherein the type of noise distribution comprises a Gaussian distribution.

7. The system according to claim 1, wherein the first and second amplifiers have the same noise distribution.

8. The system according to claim 7, wherein a signal-to-noise ratio (SNR) of the detector system is better than a detector system having a single amplifier connected to a photodiode.

9. The system according to claim 1, wherein the first amplifier is configured to supply current to the photodetector to reduce voltage droop and reduce overdrive recovery time.

10. The system according to claim 1, wherein the first and second amplifiers comprise transimpedance amplifiers.

11. The system according to claim 1, wherein the first amplifier includes a second input terminal configured to receive a first voltage threshold, and the second amplifier incudes a second input terminal configured to receive a second voltage threshold.

12. The system according to claim 11, further including a first feedback resistor coupled across the output of the first amplifier and the first input of the first amplifier, wherein the first input of the first amplifier comprises an inverting input.

13. The system according to claim 12, further including a second feedback resistor coupled across the output of the second amplifier and the first input of the second amplifier, wherein the first input of the second amplifier comprises an inverting input.

14. The system according to claim 13, further including an RC network coupled between a bias voltage and the first input of the first amplifier.

15. A method, comprising
employing a photodetector having first and second terminals, wherein the photodetector is configured to generate a current in response to light in a photodetector system;
employing a first amplifier having a first input coupled to the first terminal of the photodetector to generate a first output voltage signal corresponding to the current generated by the photodetector; and
employing a second amplifier having a first input coupled to the second terminal of the photodetector to generate a second output voltage signal corresponding to the current generated by the photodetector.

16. The method according to claim 15, wherein the photodetector comprises a photodiode, and wherein the first terminal comprises a cathode and the second terminal comprise an anode.

17. The method according to claim 15, wherein the first and second amplifiers have different linear ranges.

18. The method according to claim 17, wherein the different linear ranges of the first and second amplifiers are combined.

19. The method according to claim 15, wherein the first and second amplifiers have a same type of noise distribution.

20. The method according to claim 19, wherein the type of noise distribution comprises a Gaussian distribution.

21. The method according to claim 15, wherein the first and second amplifiers have the same noise distribution.

22. The method according to claim 21, wherein a signal-to-noise ratio (SNR) of the detector system is better than a detector system having a single amplifier connected to a photodiode.

23. The method according to claim 15, wherein the first amplifier is configured to supply current to the photodetector to reduce voltage droop and reduce overdrive recovery time.

24. The method according to claim 15, wherein the first and second amplifiers comprise transimpedance amplifiers.

25. The method according to claim 15, wherein the first amplifier includes a second input terminal configured to receive a first voltage threshold, and the second amplifier incudes a second input terminal configured to receive a second voltage threshold.

26. The method according to claim 25, further including employing a first feedback resistor coupled across the output of the first amplifier and the first input of the first amplifier, wherein the first input of the first amplifier comprises an inverting input.

27. The method according to claim 26, further including a second feedback resistor coupled across the output of the second amplifier and the first input of the second amplifier, wherein the first input of the second amplifier comprises an inverting input.

28. The method according to claim 27, further including employing an RC network coupled between a bias voltage and the first input of the first amplifier.
